(19) United States
(12) Patent Application Publication
(10) Pub. No.: US 2013/0149819 A1
(43) Pub. Date: Jun. 13, 2013

(54) THIN FILM TRANSISTORS, METHOD OF FABRICATING THE SAME, AND ORGANIC LIGHT-EMITTING DIODE DEVICE USING THE SAME

(71) Applicant: Samsung Display Co., Ltd., Yongin-city (KR)

(72) Inventors: Kyoung-Bo KIM, Suwon-si (KR); Yong-Woo Park, Suwon-si (KR); Chang-Young Jeong, Suwon-si (KR); Sung-Won Doh, Suwon-si (KR); Dae-Woo Lee, Suwon-si (KR); Jong-Mo Yeo, Suwon-si (KR)

(73) Assignee: Samsung Display Co., Ltd., Yongin-city (KR)

(21) Appl. No.: 13/760,683

(22) Filed: Feb. 6, 2013

Related U.S. Application Data
(62) Division of application No. 12/270,242, filed on Nov. 13, 2008.

(30) Foreign Application Priority Data
Nov. 13, 2007 (KR) 10-2007-115553

(51) Int. Cl. H01L 29/66

(52) U.S. Cl. CPC H01L 29/66742
USPC 438/166

(57) ABSTRACT

Aspects of the invention relate to thin film transistors, a method of fabricating the same, and an organic light-emitting diode device using the same. A thin film transistor according to an aspect of the invention includes a semiconductor layer formed from polysilicon in which a grain size deviation is within a range of substantially ±10%. Accordingly, aspects of the invention can improve non-uniformity of image characteristics due to a non-uniform grain size in polysilicon produced by a sequential lateral solidification (SLS) crystallization process.

### CROSS-REFERENCE TO RELATED APPLICATIONS

This application is a divisional of U.S. application Ser. No. 12/270,242, filed on Nov. 13, 2008, and claims the benefit of Korean Patent Application No. 10-2007-115553, filed on Nov. 13, 2007, in the Korean Intellectual Property Office, the disclosure of which is incorporated herein by reference in its entirety.

### BACKGROUND

1. Field

Aspects of the invention relate to thin film transistors, a method of fabricating the same, and an organic light-emitting diode device using the same, and more particularly, to thin film transistors including a semiconductor layer made of poly-silicon including grains having a grain size deviation of within a range of substantially ±10%, a method of fabricating the same, and an organic light-emitting diode (OLED) using the same.

2. Discussion of the Background

Generally, Flat Panel Display (FPD) devices are divided into a Liquid Crystal Display (LCD), a Field Emission Display (FED), a Plasma Display Panel (PDP), and an Organic Light-Emitting Diode (OLED) display, and so on.

The LCD and OLED can be divided into a passive matrix type and an active matrix type according to a driving method.

Since the active matrix type includes thin film transistors at all pixels within a display region, it can display a stable image by providing a constant current to all pixels.

A thin film transistor generally includes a semiconductor layer having a source/drain region and a channel region, a gate electrode, and a source/drain electrode. The semiconductor layer can be formed of either polycrystalline silicon (poly-Si) or amorphous silicon (a-Si). A better quality of thin film transistor can be obtained using poly-Si because the electron mobility of poly-Si is higher than the electron mobility of a-Si.

Generally, a method of forming a semiconductor layer of poly-Si crystallizes a-Si layers formed on a substrate by using a laser.

The crystallizing method using a laser can be mainly divided into Excimer Laser Annealing (ELA) and Sequential Lateral Solidification (SLS).

The SLS crystallizing method is a technique of enhancing the electron mobility by causing the silicon grains to grow laterally by illuminating a laser beam on an a-Si layer at least two times.

When a laser is illuminated on an a-Si layer at least two times, the second and any subsequent illumination of the laser has to be done by moving an area of the second and any subsequent illumination by a certain interval from an area of the first and any other previous illumination.

The second and any subsequent illumination of laser, however, may cause a deviation in a grain size of the semiconductor layer due to process tolerances resulting from the movement. Accordingly, the non-uniform size of grains in the semiconductor layer can cause a non-uniform image problem when driving the FPD having thin film transistors including a semiconductor layer.

### BRIEF SUMMARY OF THE INVENTION

Aspects of the invention relate to solving the aforementioned problems associated with conventional technology by forming a semiconductor layer including grains having a grain size deviation within a range of substantially ±10%.

According to an aspect of the invention, a thin film transistor includes a substrate; a semiconductor layer disposed on the substrate and including a source/drain region and a channel region; a gate electrode disposed at a position corresponding to the channel region of the semiconductor layer; an insulating layer disposed between the semiconductor layer and the gate electrode to insulate the semiconductor layer and the gate electrode from each other; and source/drain electrodes electrically connected to the source/drain region of the semiconductor layer; wherein the semiconductor layer is made of poly-Si including grains having a grain size deviation within a range of substantially ±10%.

According to an aspect of the invention, an organic light-emitting diode (OLED) includes a substrate; a semiconductor layer disposed on the substrate and including a source/drain region and a channel region; a gate electrode disposed at a position corresponding to the channel region of the semiconductor layer; a gate insulating layer disposed between the semiconductor layer and the gate electrode to insulate the semiconductor layer and the gate electrode from each other; source/drain electrodes electrically connected to the source/drain region of the semiconductor layer; a pixel electrode electrically connected to one of the source/drain electrodes; an organic layer, including an organic light-emitting layer, disposed on the pixel electrode; and an opposing electrode disposed on the organic layer; wherein the semiconductor layer is made of poly-Si including grains having a grain size deviation within a range of substantially ±10%.

According to an aspect of the invention, a method of fabricating a thin film transistor includes providing a substrate; forming a semiconductor layer including a source/drain region and a channel region on the substrate; forming a gate electrode disposed at a position corresponding to the channel region of the semiconductor layer; forming a gate insulating layer between the semiconductor layer and the gate electrode to insulate the semiconductor layer and the gate electrode from each other; and forming source/drain electrodes electrically connected to the source/drain region of the semiconductor layer; wherein the semiconductor layer is made of poly-Si including grains having a grain size deviation within a range of substantially ±10%.

According to an aspect of the invention, a thin film transistor includes a substrate; a gate electrode; and a semiconductor layer disposed between the substrate and the gate electrode. The semiconductor layer includes a source region; a drain region; and a channel region disposed between the source region and the drain region, the channel region being substantially aligned with the gate electrode. The thin film transistor further includes an insulating layer disposed between the semiconductor layer and the gate electrode; a source electrode electrically connected to the source region; and a drain electrode electrically connected to the drain region. The semiconductor layer is made of poly-Si including grains having a grain size deviation within a range of substantially ±10%.

According to an aspect of the invention, a method of fabricating a thin film transistor includes forming an amorphous silicon (a-Si) layer supported by a substrate; illuminating the a-Si layer with laser light to crystallize the a-Si layer to form a polysilicon (poly-Si) layer; forming an insulating layer so that the poly-Si layer is between the substrate and the insulating layer; forming a gate electrode so that the insulating layer is between the poly-Si layer and the gate electrode; implanting impurities into the poly-Si layer using the gate electrode as a mask to form a source region and a drain region in the poly-Si layer on opposite sides of a channel region in the poly-Si layer, the channel region being substantially aligned with the gate electrode; forming a source electrode electrically connected to the source region; and forming a drain electrode electrically connected to the drain region; wherein the poly-Si layer includes grains having a grain size deviation within a range of substantially ±10%.

Additional aspects and/or advantages of the invention will be set forth in part in the description that follows and, in part, will be obvious from the description, or may be learned by practice of the invention.

### BRIEF DESCRIPTION OF THE DRAWINGS

The above and/or other aspects and advantages of the invention will become apparent and more readily appreciated from the following description of embodiments of the invention, taken in conjunction with the accompanying drawings of which:

FIGS. 1A through 1C are sectional views showing a fabricating process of thin film transistors according to an aspect of the invention;

FIG. 2 is a sectional view of an OLED according to an aspect of the invention;

FIG. 3A through 3C are plane views showing a laser illumination process according to an Example 1 according to an aspect of the invention;

FIG. 4 is a photograph of a semiconductor layer formed in the Example 1 according to an aspect of the invention taken through an optical microscope;

FIG. 5 is a photograph of an OLED including the semiconductor formed in the Example 1 according to an aspect of the invention;

FIGS. 6A and 6B are plane views showing a laser illumination process having a mask tolerance to the right used with one mask tolerance in a Comparison Example not according to an aspect of the invention, and used with a different mask tolerance in an Example 2 according to an aspect of the invention;

FIGS. 7A and 7B are plane views showing a laser illumination process having a mask tolerance to the left used with one mask tolerance in the Comparison Example not according to an aspect of the invention, and used with a different mask tolerance in the Example 2 according to an aspect of the invention;

FIG. 8 is a photograph of a semiconductor layer formed in the Comparison Example not according to an aspect of the invention taken through an optical microscope;

FIG. 9 is a photograph of an OLED including the semiconductor formed in the Comparison Example not according to an aspect of the invention;

FIG. 10 is a photograph of a semiconductor layer formed in the Example 2 according to an aspect of the invention taken through an optical microscope; and

FIG. 11 is a photograph of an OLED including the semiconductor formed in the Example 2 according to an aspect of the invention.

### DETAILED DESCRIPTION OF THE INVENTION

Reference will now be made in detail to embodiments of the invention, examples of which are shown in the accompanying drawings, wherein like reference numerals refer to like elements throughout, and the thickness and the length of layers and regions may be exaggerated for convenience of explanation. The embodiments are described below in order to explain the invention by referring to the figures.

In the following description, it is understood that when a first layer is described as being “formed on” or “disposed on” a second layer, the first layer may be formed or disposed directly on the second layer, or there may be one or more intervening layers between the first layer and the second layer. Also, it is understood that the term “formed on” has the same meaning as “located on” or “disposed on,” and is not meant to be limiting regarding any particular fabrication process. Also, it is understood that when a first layer is described as being “disposed between” or “between” a second layer and a third layer, the first layer may be disposed directly between the second layer and the third layer, or there may be one or more intervening layers between the first layer and the second layer, and/or between the first layer and the third layer.

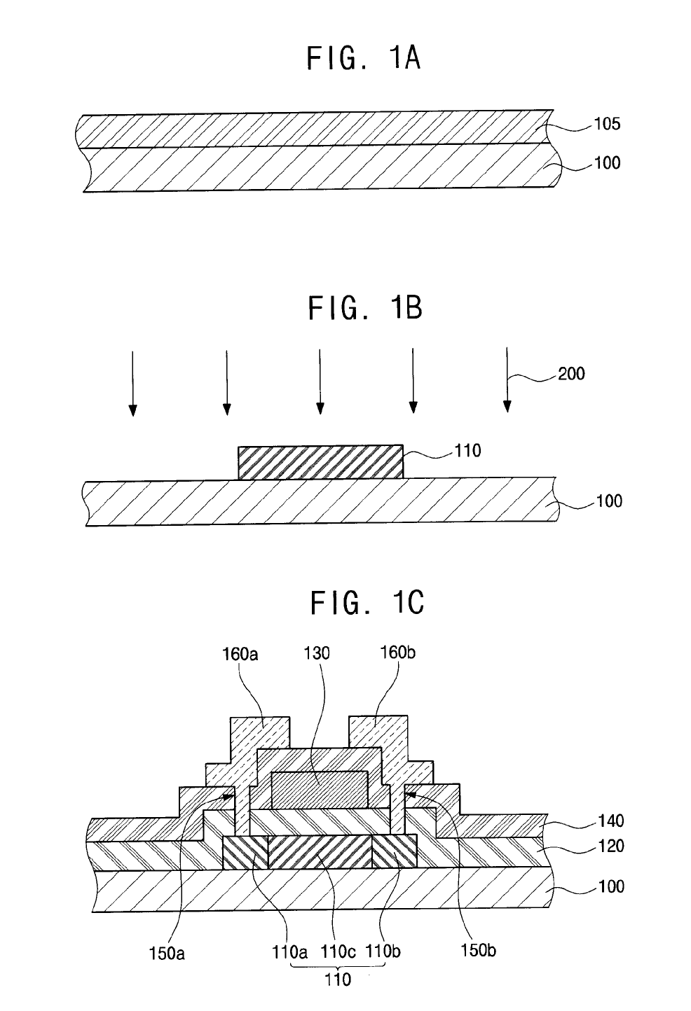

FIGS. 1A through 1C are sectional views showing a fabricating process of thin film transistors according to an aspect of the invention.

Referring to FIG. 1A, a buffer layer (not shown) may be formed on a substrate 100. Then, an a-Si layer 105 may be formed on the buffer layer.

Referring to FIG. 1B, the a-Si layer 105 may be crystallized to form a poly-Si layer by carrying out a Sequential Lateral Solidification (SLS) crystallization process 200.

Next, the poly-Si layer may be patterned to form a semiconductor layer 110.

According to an aspect of the invention, the semiconductor layer 110 may be formed so that grains formed during the SLS crystallization have a grain size deviation within a range of substantially ±10%.

Performing the SLS crystallization so that grains formed during the SLS crystallization have a grain size deviation within a range of substantially ±10% is difficult. Further, if the grain size deviation in the semiconductor layer is outside the range of substantially ±10%, non-uniform image characteristics may occur when driving an OLED including thin film transistors including such a semiconductor layer.

A grain size deviation that occurs during SLS crystallization will be explained below with respect to Examples according to aspects of the invention and Comparison Examples not according to aspects of the invention.

Referring to FIG. 1C, a gate insulating layer 120 may be formed over a substrate on which the semiconductor layer 110 is formed, so that the gate insulating layer 120 may protect layers formed therebelow and electrically insulate any layers to be formed over the gate insulating layer 120 from the layers formed therebelow.

Next, a gate metallic layer (not shown) made of a material selected from the group consisting of aluminum, aluminum alloy, molybdenum (Mo), and molybdenum alloy (Mo alloy) may be formed on the gate insulating layer 120. However, it is understood that the gate metallic layer may be made of any other suitable material.

Next, a gate electrode 130 may be formed at a position corresponding to a certain region of the semiconductor layer 110 by patterning the gate metallic layer.

Next, either N type or P type impurities may be implanted into the substrate using the gate electrode 130 as a mask to form a source/drain region 110a and 110b and a channel region 110c. The region into which the impurities are introduced is defined as the source/drain region 110a and 110b, and the region into which the impurities are not introduced due to the gate electrode 130 masking the impurities is defined as the channel region 110c. It is understood that the region 110a may be a source region and the region 110b may be a drain region, or the region 110a may be a drain region and the region 110b may be a source region.

Next, an interlayer insulating layer 140 may be formed over the substrate for protecting any layers formed therebelow and electrically insulating any layers to be formed thereabove from the layers formed therebelow.

The buffer layer (not shown), the gate insulating layer 120, and the interlayer insulating layer 140 may be made of SiO₂ or SiNx, or may be made of a multilayer of SiO₂ and SiNx.

Next, contact holes 150a and 150b passing through the interlayer insulating layer 140 and the gate insulating layer 120 may be formed to expose respective portions of the source/drain region 110a and 110b of the semiconductor layer 110.

Next, the thin film transistor may be completed by forming patterned source/drain electrodes 160a and 160b connected to the source/drain region 110a and 110b of the semiconductor layer 110 through the contact holes 150a and 150b on the interlayer insulating layer 140.

The source/drain electrodes 160a and 160b may be made of a material selected from the group consisting of aluminum, aluminum alloy, molybdenum (Mo), and molybdenum alloy (Mo alloy). However, it is understood that the source/drain electrodes 160a and 160b may be made of any other suitable material.

The thin film transistor according to an aspect of the invention shown in FIG. 1C has a top gate electrode structure. However, aspects of the invention are not limited thereto, but may be equally applied to a conventional bottom gate electrode structure.

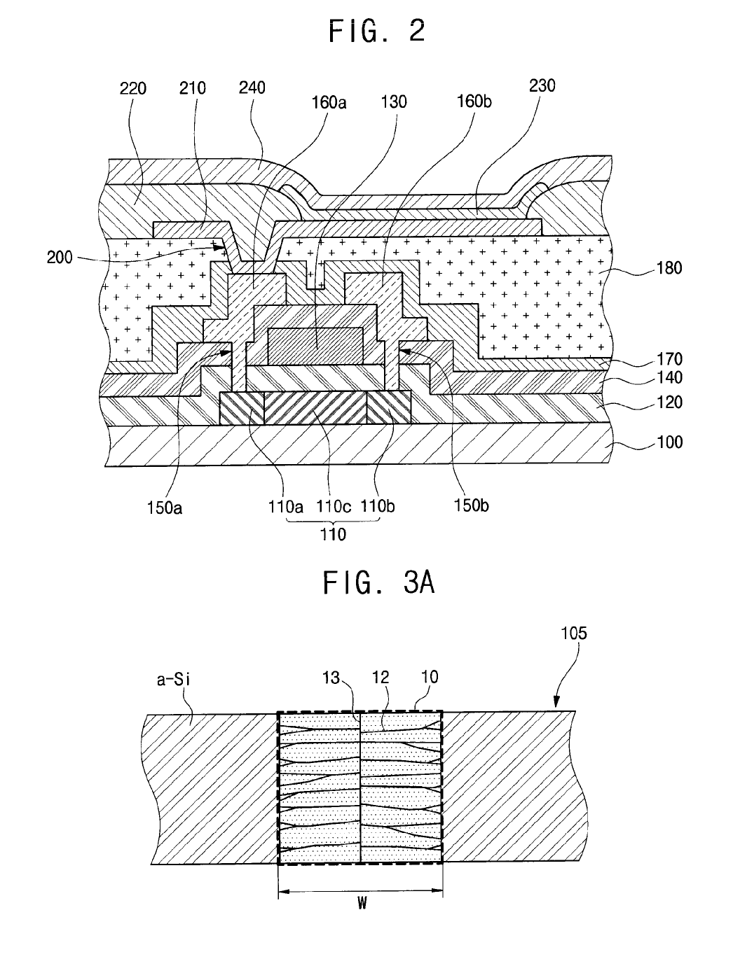

FIG. 2 is a sectional view of an OLED according to an aspect of the invention.

Referring to FIG. 2, a protection layer 170 may be formed on an entire surface of the thin film transistor including a semiconductor layer 110 in which a grain size deviation is within a range of substantially ±10% according to an aspect of the invention. The protection layer 170 may be made of SiO₂ or SiNx, or may be made of a multilayer of SiO₂ and SiNx. However, it is understood that the protection layer 170 may be made of any other suitable material.

Next, a planarization layer 180 may be formed on the protection layer 170. It is preferable that the planarization layer 180 is an organic film and is made of a photosensitive material selected from the group consisting of acrylic, benzocyclobutene (BCB), and polyimide.

However, it is understood that the planarization layer 180 may be made of any other suitable material.

Next, a via hole 200 exposing one of the source/drain electrodes 160a and 160b may be formed by etching both the planarization layer 180 and the protection layer 170.

Next, pixel electrodes 210 made of a transparent electrode material such as Indium Tin Oxide (ITO) and/or Indium Zinc Oxide (IZO) may be formed on the planarization layer 180, and connected to the exposed one of the source/drain electrodes 160a and 160b through the via hole 200. However, it is understood that the pixel electrodes 210 may be made of any other suitable material.

The pixel electrodes 210 may have a structure in which a transparent electrode material such as Indium Tin Oxide (ITO) and/or Indium Zinc Oxide (IZO) is stacked on a reflection layer (not shown) made of a material selected from the group consisting of Pt, Au, Ir, Cr, Mg, Ag, Al, and alloys thereof. However, it is understood that the reflection layer may be made of any other suitable material.

Next, a pixel-defining layer 220 having an opening exposing a certain region of the pixel electrodes 210 may be formed over the whole substrate. The pixel-defining layer 220 may be made of a material selected from the group consisting of benzocyclobutene (BCB), high molecular weight acrylic, and polyimide. However, it is understood that the pixel-defining layer 220 may be made of any other suitable material.

Next, an organic layer 230 including an organic light-emitting layer (not shown) may be formed on the region of the pixel electrodes 210 exposed by the opening of the pixel-defining layer 220, and an opposing electrode 240 may be formed on the pixel-defining layer 220 and the organic layer 230 over the entire top surface of the OLED, thereby completing the fabrication of the OLED.

A relationship between a grain size deviation in the semiconductor layer 110 crystallized using SLS and image characteristics of an OLED including the semiconductor layer 110 will be described below with reference to Examples according to aspects of the invention and Comparison Examples not according to aspects of the invention.

### Example 1

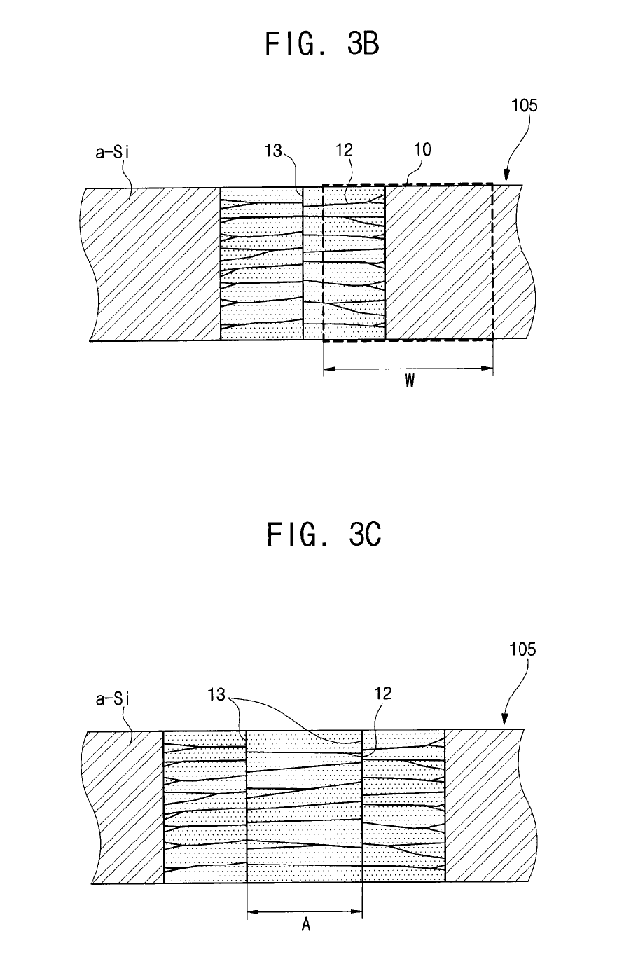

FIG. 3A through 3C are plane views showing a laser illumination process in an Example 1 according to an aspect of the invention.

Referring to FIG. 3A, an opening of a mask 10 having a width W may be positioned on an a-Si layer 105 formed on a substrate.

Next, the a-Si layer 105 is illuminated with laser light through the opening having the width W in a first laser illumination.

The first laser illumination immediately melts the a-Si layer 105 exposed by the opening having the width W. Such a laser crystallization method has the advantage of forming polysilicon having a superior crystallinity while minimizing an amount of heat transferred to the substrate.

Next, as the melted portion of the a-Si layer 105 cools down after the first laser illumination is finished, crystallization of the melted portion of the a-Si layer 105 begins, starting at the boundaries between the unmelted portion of the a-Si layer 105 and the melted portion of the a-Si layer 105.

The temperature of the melted portion of the a-Si layer 105 gradually decreases from the center of the melted portion toward the positions of the boundaries between the unmelted portion of the a-Si layer 105 and the melted portion of the a-Si layer 105 as a result of the latent heat of fusion that causes heat to be absorbed by seed formation occurring at the boundaries.

Meanwhile, the crystallization of the melted portion of the a-Si layer 105 progresses toward the center of the melted portion, and the resulting polysilicon region grows laterally until the melted portion is completely solidified. Accordingly, many grains are formed in parallel in a direction of a current flow in the semiconductor layer, i.e., in a direction between the source region and the drain region.

A boundary is formed at an interface between a grain and an adjacent grain growing parallel to the grain. Such a boundary is substantially parallel to a growing direction of the grains, and is referred to as a secondary grain boundary 12.

Further, since the grains of the polysilicon are simultaneously growing toward the center of the melted portion of the a-Si layer 105 from both boundaries between the unmelted portion of the a-Si layer 105 and the melted portion of the a-Si layer 105, the growth of the grains stops when the grains meet at the center of the melted portion of the a-Si layer 105. Accordingly, a different type of boundary is formed where grains growing in opposite directions meet each other. Such a boundary is substantially perpendicular to the growing direction of the grains, and is referred to as a primary grain boundary 13.

Next, referring to FIG. 3B, by moving a stage (not shown) supporting the substrate on which the a-Si layer 105 is formed a certain distance to the left, the mask 10, which is fixed in place, is moved to the right relative to the substrate by the same distance that the stage moves.

More specifically, a second laser illumination is performed after moving the mask 10 to the right by more than 50% but less than 100% of the width W of the region of the a-Si layer 105 that was illuminated in the first laser illumination, after the first laser illumination is finished.

Accordingly, the opening of the mask 10 having the width W is positioned on a region of the a-Si layer 105 including an interface between the polysilicon region of the a-Si layer 105 in which grains were formed by the first laser illumination and an a-Si region of the a-Si layer 105.

Next, the second laser illumination is performed on the polysilicon region and the a-Si region through the opening of the mask 10, thereby immediately melting the silicon in the illuminated regions.

The second laser illumination is performed after a separate aligning process is performed to remove any mask tolerance resulting from the stage movement.

Next, referring to FIG. 3C, the length of the grains is increased as a result of the second laser illumination because as the melted silicon solidifies, the silicon atoms attach themselves to the grains of the polysilicon that were previously formed by the first laser illumination.

Further, since the grains of the polysilicon simultaneously grow toward the center of the melted portion of the a-Si layer 105 from both boundaries between the unmelted portion of the a-Si layer 105 and the melted portion of the a-Si layer 105, the growth of the grains stops when the grains meet at the center of the melted portion of the a-Si layer 105.

Accordingly, another primary boundary 13 is formed where grains growing in opposite directions meet each other. A distance between adjacent primary boundaries 13 is a grain size (A).

Finally, the semiconductor layer 110 shown in FIG. 1B is formed by patterning the polysilicon after converting the a-Si silicon layer 105 into the polysilicon by repetitively moving the mask relative to the substrate and performing a laser illumination like the second laser illumination.

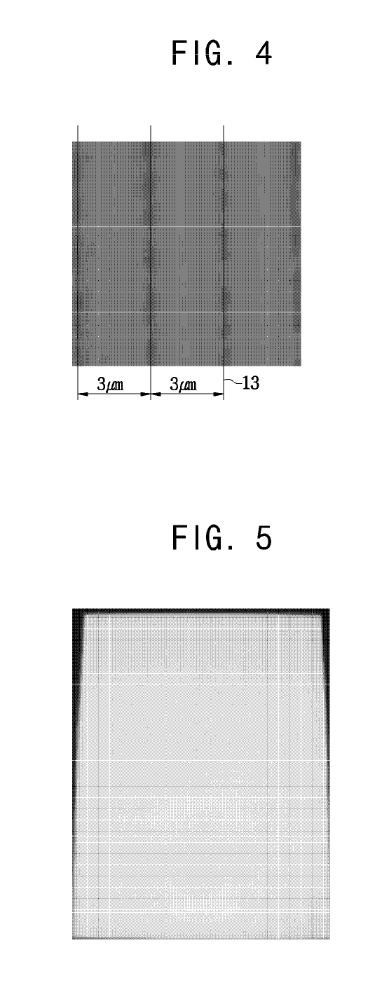

FIG. 4 is a photograph of the semiconductor layer formed in the Example 1 according to an aspect of the invention taken through an optical microscope.

Referring to FIG. 4, the grain size (A) of the grains formed in the semiconductor layer is substantially equal to 3 μm without any deviation in grain size. Thus, the grains have a substantially uniform grain size of 3 μm, such that they have a grain size deviation of substantially zero.

FIG. 5 is a photograph of an OLED including the semiconductor layer formed in the Example 1 according to an aspect of the invention.

The OLED shown in FIG. 5 includes thin film transistors including a semiconductor layer formed according to the Example 1 according to an aspect of the invention in which the grains have a substantially uniform grain size of 3 μm without any grain size deviation as shown in FIG. 4.

The OLED shown in FIG. 5 is being driven by applying a uniform voltage to all of the pixels of the OLED, which ideally should cause the OLED to display a uniform image having a uniform brightness level over the entire surface of the OLED. As can be seen in FIG. 5, the OLED is displaying such a uniform image.

### Comparison Example

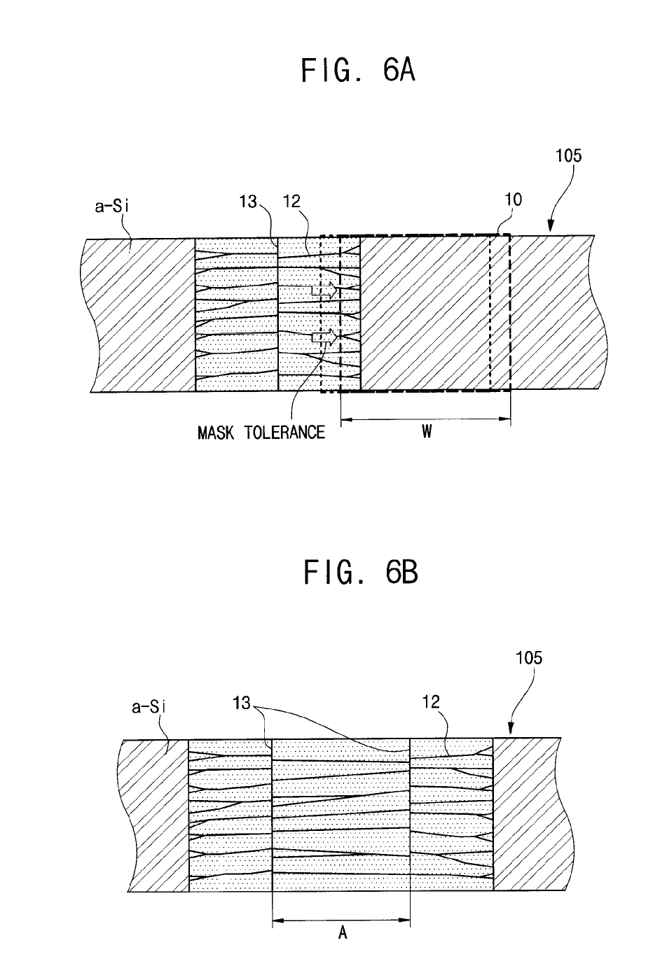

FIGS. 6A and 6B are plane views showing a laser illumination process having a mask tolerance to the right used in a Comparison Example not according to an aspect of the invention.

The Comparison Example not according to an aspect of the invention is identical to the Example 1 according to an aspect of the invention except for the second laser illumination. Accordingly, a detailed description of the Comparison Example will be provided only for the second laser illumination.

First, referring to FIG. 6A, a first laser illumination is performed using the same method used in FIG. 3A. Next, by moving a stage (not shown) supporting the substrate a certain distance to the left, the mask 10, which is fixed in place, is moved to the right relative to the substrate by the same distance that the stage moves.

More specifically, a second laser illumination is performed after moving the mask 10 to the right by more than 50% but less than 100% of the width W of the region of the a-Si layer 105 that was illuminated in the first laser illumination, after the first laser illumination is finished.

Accordingly, the opening of the mask 10 having the width W is positioned on a region of the a-Si layer 105 including an interface between the polysilicon region of the a-Si layer 105 in which grains were formed by the first laser illumination and an a-Si region of the a-Si layer 105.

In order to determine any effect of a mask tolerance resulting from the stage movement, the mask 10 is shifted from an intended mask position of 3 μm to the right of the previous mask position by a mask tolerance of about 0.45 μm to the right as shown in FIG. 6A, i.e., to a new mask position of 3.45 μm to the right of the previous mask position.

Next, a second laser illumination is performed through the opening of the mask 10, thereby immediately melting the a-Si and the polysilicon corresponding to the opening of the mask 10.

Next, the a-Si and the polysilicon melted in the second laser illumination cool and solidify, thereby forming grains of polysilicon.

Next, referring to FIG. 6B, the length of the grains is increased as a result of the second laser illumination because as the melted silicon solidifies, the silicon atoms attach themselves to the grains of the polysilicon that were previously formed by the first laser illumination.

Further, since the grains of the polysilicon simultaneously grow toward the center of the melted portion of the a-SI layer 105 from both boundaries between the melted portion and the unmelted portion of the a-Si layer 105, the growth of the grains stops when the grains meet at the center of the melted portion.

Accordingly, another primary boundary 13 is formed where grains growing in opposite directions meet each other. A distance between adjacent primary boundaries 13 is a grain size (A).

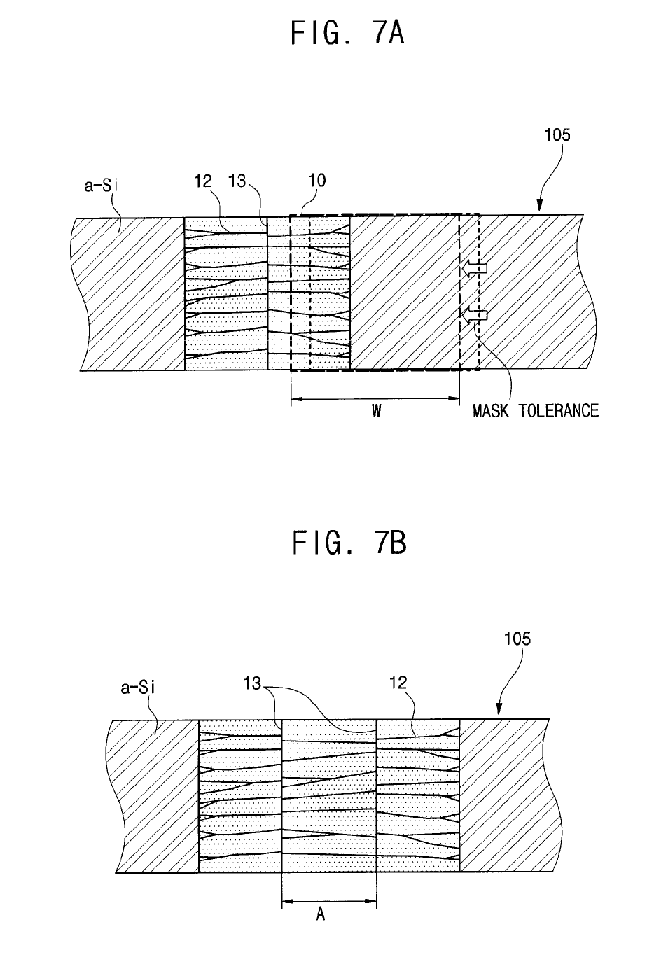

FIGS. 7A and 7B are plane views showing a laser illumination process having a mask tolerance to the left used in the Comparison Example not according to an aspect of the invention.

First, referring to FIG. 7A, a first laser illumination is performed using the same method used in FIG. 3A. Next, by moving a stage (not shown) supporting the substrate a certain distance to the left, a mask 10, which is fixed in place, is moved to the right relative to the substrate by the same distance that the stage moves.

More specifically, a second laser illumination is performed after moving the mask 10 to the right by more than 50% but less than 100% of the width W of the region of the a-Si layer 105 that was illuminated in the first laser illumination, after the first laser illumination is finished.

Accordingly, the opening of the mask 10 having the width W is positioned on a region of the a-Si layer 105 including an interface between the polysilicon region of the a-Si layer 105 in which grains were formed by the first laser illumination and an a-Si region of the a-m Si layer 105.

In order to determine any effect of a mask tolerance resulting from the stage movement, the mask 10 is shifted from an intended mask position of 3 μm to the right of the previous mask position by a mask tolerance of about 0.45 μm to the left as shown in FIG. 7B, i.e., to a new mask position of 2.55 μm to the right of the previous mask position.

Next, a second laser illumination is performed through the opening of the mask 10, thereby immediately melting the a-Si and the polysilicon corresponding to the opening of the mask 10.

Next, the a-Si and the polysilicon melted in the second laser illumination cool and solidify, thereby forming grains of polysilicon,

Next, referring to FIG. 7B, the length of the grains is increased as a result of the second laser illumination because as the melted silicon solidifies, the silicon atoms attach themselves to the grains of the polysilicon that were previously formed by the first laser illumination.

Further, since the grains of the polysilicon simultaneously grow toward the center of the melted portion of the a-Si layer 105 from both boundaries between the melted portion and the unmelted portion of the a-Si layer 105, the growth of the grains stops when the grains meet at the center of the melted portion.

Accordingly, another primary boundary 13 is formed where grains growing in opposite directions meet each other. A distance between adjacent primary boundaries 13 is a grain size (A).

Finally, the semiconductor layer 110 shown in FIG. 1B is formed by patterning the polysilicon after converting the a-Si layer 105 into the polysilicon by repetitively moving the mask relative to the substrate and performing a laser illumination like the second laser illumination.

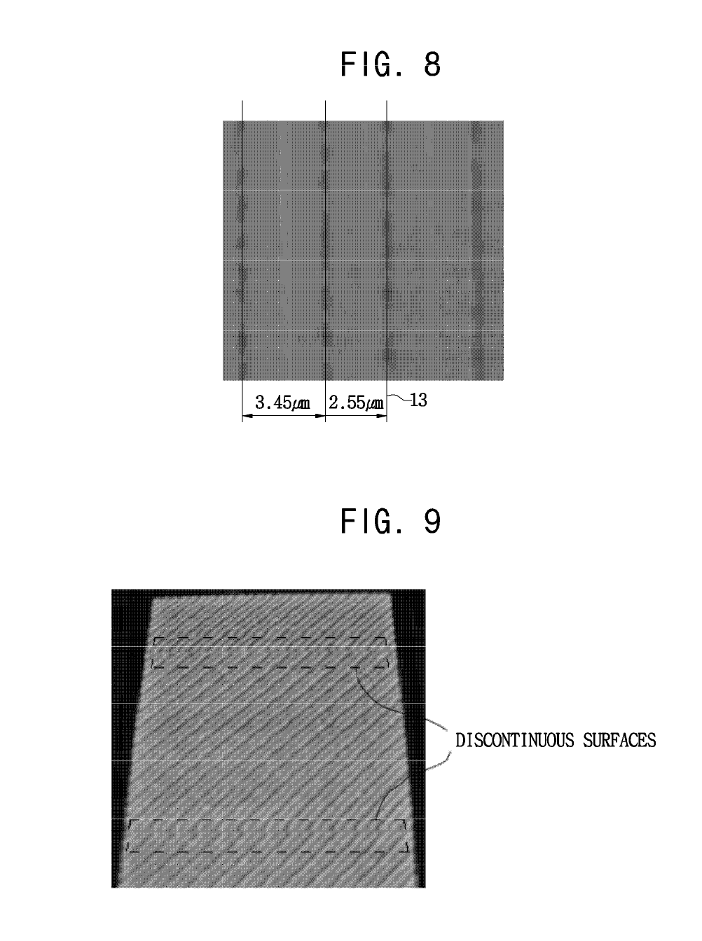

FIG. 8 is a photograph of the semiconductor formed in the Comparison Example not according to an aspect of the invention taken through an optical microscope.

Referring to FIG. 8, the grain sizes (A) of the grains formed in the semiconductor layer in the Comparison Example not according to an aspect of the invention are about 3.45 μm and 2.55 μm as a result of shifting the mask 10 to the right and the left by the mask tolerance of 0.45 μm from the intended mask position of 3 μm as shown in FIGS. 6A and 7A, compared to a grain size of 3 μm in the Example 1 according to an aspect of the invention in which there is no mask tolerance.

Thus, the grain size deviation in the semiconductor layer formed in the Comparison Example is 3 μm±0.45 μm, i.e., is within a range of substantially ±15%.

FIG. 9 is photograph of an OLED including the semiconductor formed in the Comparison Example not according to an aspect of the invention.

Referring to FIG. 9, the OLED shown in FIG. 9 includes thin film transistors including a semiconductor layer formed according to the Comparison Example not according to an aspect of the invention having a grain size deviation within a range of substantially ±15%.

The OLED shown in FIG. 9 is being driven by a applying a uniform voltage to all of the pixels of the OLED, which should ideally cause the OLED to display a uniform image having a uniform brightness level over the entire surface of the OLED. However, as can be seen in FIG. 9, the OLED is displaying a non-uniform image in which slant-line-type discontinuous surfaces appear.

### Example 2

FIGS. 6A and 6B are plane views showing a laser illumination process having a mask tolerance to the right used in an Example 2 according to an aspect of the invention.

The Example 2 according to an aspect of the invention is identical to the Example 1 according to an aspect of the invention except for the second laser illumination. Accordingly, a detailed description of the Example 2 will be omitted will be provided only for the second laser illumination.

First, referring to FIG. 6A, a first laser illumination is performed using the same method used in FIG. 3A. Next, by moving a stage (not shown) supporting the substrate a certain distance to the left, a mask 10, which is fixed in place, is moved to the right relative to the substrate by the same distance that the stage moves.

More specifically, a second laser illumination is performed after moving the mask 10 to the right by more than 50% but less than 100% of the width W of the region of the a-Si layer 105 that was illuminated in the first laser illumination, after the first laser illumination is finished.

Accordingly, the opening of the mask 10 having the width W is positioned on a region of the a-Si layer 105 including an interface between the polysilicon region of the a-Si layer 105 in which grains are formed by the first laser illumination and an a-Si region of the a-Si layer 105.

In order to determine any effect of a mask tolerance resulting from the stage movement, the mask 10 is shifted from an intended mask position of 3 μm to the right of the previous mask position by a mask tolerance of about 0.3 μm to the right as shown in FIG. 6A, i.e., to a new mask position of 3.3 μm to the right of the previous mask position.

Next, a second laser illumination is performed through the opening of the mask 10, thereby immediately melting the a-Si and the polysilicon corresponding to the opening of the mask 10.

Next, the a-Si and the polysilicon melted in the second laser illumination cool and solidify, thereby forming grains of polysilicon.

Next, referring to FIG. 6B, the length of the grains is increased as a result of the second laser illumination because as the melted silicon solidifies, the silicon atoms attach themselves to the grains of the polysilicon that were previously formed by the first laser illumination.

Further, since the grains of the polysilicon simultaneously grow toward the center of the melted portion of the a-Si layer 105 from both boundaries between of the melted portion and the unmelted portion of the a-Si layer 105, the growth of the grains stops when the grains meet at the center of the melted portion.

Accordingly, another primary boundary 13 is formed where grains growing in opposite directions meet each other. A distance between adjacent primary boundaries 13 is a grain size (A).

FIGS. 7A and 7B are plane views showing a laser illumination process having a mask tolerance to the left used in the Example 2 according to an aspect of the invention.

First, referring to FIG. 7A, a first laser illumination is performed using the same method used in FIG. 3A. Next, by moving a stage (not shown) supporting the substrate a certain distance to the left, a mask 10, which is fixed in place, is moved to the right relative to the substrate by the same distance that the stage moves.

More specifically, a second laser is performed after moving the mask 10 to the right by more than 50% but less than 100% of the width W of the region of the a-SI layer 105 that was illuminated in the first laser illumination, after the first laser illumination is finished.

Accordingly, the opening of the mask 10 having the width W is positioned on a region of the a-Si layer 105 including an interface between the polysilicon region of the a-Si layer in which grains were formed by the first laser illumination and an a-Si region of the a-Si layer 105.

In order to determine any effect of a mask tolerance resulting from the stage movement, the mask 10 is shifted from an intended mask position of 3 μm to the right of the previous mask position by a mask tolerance of about 0.3 μm to the left as shown in FIG. 7B, i.e., to a new mask position of 2.7 μm to the right of the previous mask position.

Next, a second laser illumination is performed through the opening of the mask 10, thereby immediately melting the a-Si and the polysilicon corresponding to the opening of the mask 10.

Next, the a-Si and the polysilicon melted in the second laser illumination cool and solidify, thereby forming grains of polysilicon.

Next, referring to FIG. 7B, the length of the grains is increased as a result of the second laser illumination because as the melted silicon solidifies, the silicon atoms attach themselves to the grains of the polysilicon that were previously formed by the second laser illumination.

Further, since the grains of the polysilicon simultaneously grow toward the center of the melted portion of the a-Si layer 105 from both boundaries between the melted portion and the unmelted portion of the a-Si layer 105, the growth of the grains stops when the grains meet at the center of the melted portion.

Accordingly, another primary boundary 13 is formed where grains growing in opposite directions meet each other. A distance between adjacent primary boundaries 13 is a grain size (A).

Finally, the semiconductor layer 110 shown in FIG. 110B is formed by patterning the polysilicon after converting the a-Si layer 105 into the polysilicon by repetitively moving the mask relative to the substrate and performing a laser illumination like the second laser illumination.

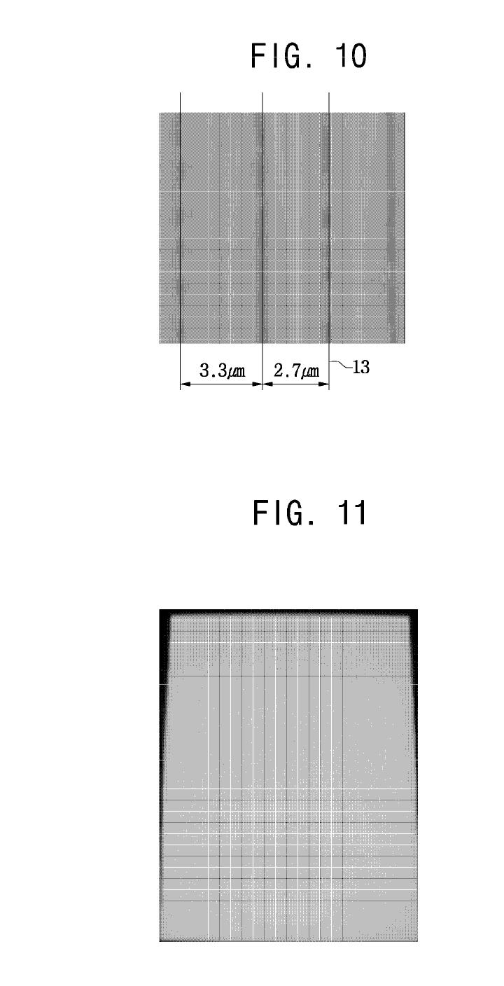

FIG. 10 is a photograph of the semiconductor layer formed in the Example 2 according to an aspect of the invention taken through an optical microscope.

Referring to FIG. 10, the grain sizes (A) of the grains formed in the semiconductor layer in the Example 2 according to an aspect of the invention are about 3.3 μm and 2.7 μm as a result of shifting the mask 10 to the right and the left by the mask tolerance of 0.45 μm from the intended mask position of 3 μm as shown in FIGS. 6A and 7A, compared to a grain size of 3 μm in the Example 1 according to an aspect of the invention in which there is no mask tolerance.

Thus, the grain size deviation (A) in the semiconductor layer formed in the Example 2 according to an aspect of the invention is 3 μm±0.3 μm, i.e., is within a range of substantially ±10%.

FIG. 11 is a photograph of an OLED including the semiconductor layer formed in the Example 2 according to an aspect of the invention.

Referring to FIG. 11, the OLED shown in FIG. 9 includes thin film transistors including a semiconductor layer formed according to the Example 2 according to an aspect of the invention having grain size deviation within a range of substantially 10%.

The OLED shown in FIG. 11 is being driven by applying a uniform voltage to all of the pixels of the OLED, which should ideally cause the OLED to display a uniform image having a uniform brightness level over the entire surface of the OLED. As can be seen from FIG. 11, the OLED is displaying such a uniform image.

Thus, it should be appreciated that there is no significant difference between the image shown in FIG. 5 that is displayed on the OLED of the Example 1 according to an aspect of the invention in which the grain size deviation is substantially zero, and the image shown in FIG. 11 that is displayed on the OLED of the Example 2 according to an aspect of the invention in which the grain size deviation is within a range of substantially ±10%.

Accordingly, it will be appreciated that superior image characteristics are obtained by forming the semiconductor layer as polysilicon including grains having a grain size deviation within a range of substantially ±10%.

Although several embodiments of the invention have been shown and described, it would be appreciated by those skilled in the art that changes may be made in these embodiments without departing from the principles and spirit of the invention, the scope of which is defined in the claims and their equivalents.

What is claimed is:

1. A method of fabricating a thin film transistor, comprising:
forming a semiconductor layer comprising source/drain regions and a channel region, on a substrate;
forming a gate insulating layer on the semiconductor layer;
forming a gate electrode on the gate insulating layer and adjacent to the channel region of the semiconductor layer; and
forming source/drain electrodes electrically connected to the source/drain regions of the semiconductor layer;
wherein the semiconductor layer is made of poly-Si comprising grains having a grain size deviation within a range of substantially ±10%.

2. The method of claim 1, wherein the semiconductor layer is crystallized by a sequential lateral solidification (SLS) crystallization method.

3. The method of claim 1, wherein a growing direction of the grains is parallel to a direction of a current flow in the semiconductor layer.

4. The method claim 1, wherein the grain size is a distance between adjacent grain boundaries that are perpendicular to a growing direction of the grains.

5. The method of claim 1, wherein the semiconductor layer is crystallized by illuminating the semiconductor layer with a laser through an opening in a mask.

6. The method of claim 1, wherein the semiconductor layer is crystallized by illuminating the semiconductor layer with a laser at least two times.

7. The method of claim 1, wherein the semiconductor layer is crystallized by:
illuminating a first region of the semiconductor laser light in a first laser illumination; and
illuminating a second region of the semiconductor layer with laser light in a second laser illumination so that the second region overlaps the first region and is moved relative to the first region by more than 50% of a width of the first region.

8. A method of fabricating a thin film transistor comprising:
forming an amorphous silicon (a-Si) layer supported by a substrate;
illuminating the a-Si layer with laser light to crystallize the a-Si layer to form a polysilicon (poly-Si) layer;
forming an insulating layer so that the poly-Si layer is between the substrate and the insulating layer;
forming a gate electrode so that the insulating layer is between the poly-Si layer and the gate electrode;
implanting impurities into the poly-Si layer using the gate electrode as a mask to form a source region and a drain region in the poly-Si layer on opposite sides of a channel region in the poly-Si layer, the channel region being substantially aligned with the gate electrode;
forming a source electrode electrically connected to the source region; and
forming a drain electrode electrically connected to the drain region;
wherein the poly-Si layer comprises grains having a grain size deviation within a range of substantially ±10%.

9. The method of claim 8, wherein the illuminating of the a-Si layer comprises illuminating the a-Si layer with a laser through an opening in a mask a plurality of times, the mask being moved relative to the substrate by more than 50% and less than 100% of a width of the opening of the mask between each of the illuminations of the a-Si layer.
